(19) United States
(12) Patent Application Publication
(10) Pub. No.: US 2017/0084680 A1
(43) Pub. Date: Mar. 23, 2017

(54) Methods for Forming High-K Dielectric Materials with Tunable Properties

(71) Applicant: Intermolecular, Inc., San Jose, CA (US)

(72) Inventors: Howard Lin, Santa Clara, CA (US); Gaurav Saraf, San Jose, CA (US); Kiet Vuong, San Jose, CA (US)

(73) Assignee: Intermolecular, Inc., San Jose, CA (US)

(21) Appl. No.: 15/264,877

(22) Filed: Sep. 14, 2016

Related U.S. Application Data
(60) Provisional application No. 62/220,048, filed on Sep. 17, 2015.

(51) Int. Cl. H01L 49/02; H01L 21/02

(52) U.S. Cl. CPC H01L 28/55; H01L 21/02189; H01L 21/02181; H01L 21/02186; H01L 21/02329; H01L 21/02266

(57) ABSTRACT

Embodiments provided herein describe methods and systems for forming high-k dielectric materials, as well as devices that utilize such materials. A property of a high-k dielectric material is selected. A value of the selected property of the high-k dielectric material is selected. A chemical composition of the high-k dielectric material is selected from a plurality of chemical compositions of the high-k dielectric material. The selected chemical composition of the high-k dielectric material includes an amount of nitridation associated with the selected value of the selected property of the high-k dielectric material. The high-k dielectric material is formed with the selected chemical composition.

### CROSS-REFERENCE TO RELATED APPLICATIONS

This application claims priority to U.S. Provisional Patent Application Ser. No. 62/220,048 filed on Sep. 17, 2015, which is herein incorporated by reference for all purposes.

### TECHNICAL FIELD

The present invention relates to high-k dielectric materials. More particularly, this invention relates to methods for forming high-k dielectric materials in such a way that various properties, such as phase, crystallinity, optical, and electrical properties, may be tuned.

### BACKGROUND

Research efforts on high-k materials with dielectric constants higher than 7 is critical to replacing conventional dielectrics, such as silicon oxide, in order to realize the continuous reduction device size (e.g., semiconductor devices, display storage capacitors, etc.) and storage capability scaling (e.g., with respect to dynamic random-access memory (DRAM)). To enable and utilize such materials, phase and/or crystal structure plays a critical role. Additionally, in real-world applications, the use of high-k materials often requires not only the correct material phase, but the material's passivation, crystallinity, film etchability, defect density, surface and interface roughness, etc. are also very important to solving integration challenges.

As a result, the tunability of phase, crystallinity, dielectric constant, optical properties, etc. is extremely important for high-k dielectrics. However, it is desirable to obtain such control of these characteristics of the material(s) while utilizing current manufacturing processes, methods, and materials, while maintaining (or improving) electrical/device performance with respect to, for example, dielectric constant, leakage current density, and dielectric relaxation.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a graph showing the refractive index of a high-k dielectric material as the chemical composition of a gaseous environment in the processing chamber in which the material is formed is changed.

FIG. 2 is a graph showing the leakage density and dielectric constant of a high-k dielectric material as the chemical composition of a gaseous environment in the processing chamber in which the material is formed is changed.

FIG. 3 is a graph showing the leakage density and dielectric constant of a high-k dielectric material as the chemical composition of the high-k dielectric material is changed.

FIG. 4 is a cross-sectional view of a substrate with a thin-film transistor and a storage capacitor formed above according to some embodiments.

FIG. 5 is a simplified cross-sectional diagram illustrating a physical vapor deposition (PVD) tool according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide methods for forming high dielectric constant (i.e., high-k dielectric) materials in such a way that various properties may be tuned. The properties (or characteristics) of the high-k dielectric that may be tuned may include, for example, phase, crystallinity, dielectric constant, dielectric relaxation (e.g., to reduce dielectric relaxation), capacitance vs. frequency dependence (e.g., to reduce capacitance vs. frequency dependence), and leakage density (e.g., reduce leakage density). In some embodiments, the tunability of the high-k dielectric is performed by subjecting the material to a nitridation (or nitridization) process and/or selecting a chemical composition for the high-k dielectric with a particular amount of nitridation.

In some embodiments, the nitridation process is performed during the formation or deposition process (i.e., in-situ). For example, the nitridation process may be performed during and/or as part of a deposition process such as physical vapor deposition (PVD) (e.g., reactive or radio-frequency (RF)), chemical vapor deposition (CVD), plasma-enhanced CVD (PECVD), atomic layer deposition (ALD), etc. In some embodiments, the nitridation is performed by depositing the high-k dielectric (e.g., via PVD) in a gaseous environment comprising between 0% and 100% nitrogen gas by volume (e.g., nitrogen gas mixed with argon gas and/or oxygen gas). In some embodiments, the nitridation is performed by incorporating the nitrogen into the targets from which the high-k dielectric are deposited (or sputtered).

In some embodiments, the nitridation process is performed after the formation/deposition process (i.e., ex-situ). For example, the nitridation process may be performed plasma processes (e.g., remote plasma treatments or direct plasma treatments, such as nitrogen, ammonia, etc) or non-plasma processes, such as gas treatments, annealing processes (e.g., in a gaseous environment including elemental or molecular nitrogen), chemical treatments, etc.

The tuned high-k dielectric material(s) may include materials with a dielectric constant (k) greater than 7, such as magnesium-zirconium oxynitride, zirconium oxynitride, hafnium oxynitride, titanium oxynitride, or a combination thereof. The tuning (e.g., nitridation) process may be applicable to single, bi-layer, or multi-layer dielectric “stacks” and may be applied to the bulk of the material and/or to the interfaces between multiple layers (e.g., of high-k dielectric materials or other materials). The tuned high-k dielectric material(s) may be utilized in, for example, display storage capacitors, dynamic random-access memory (DRAM) devices, and other types of devices (e.g., semiconductor devices).

In one series of experiments, magnesium-zirconium oxide and magnesium-zirconium oxynitride layers were formed using PVD in gaseous environments ranging from 0% nitrogen gas to 100% nitrogen gas (e.g., 100% argon, 25% nitrogen and 75% argon, 50% nitrogen and 50% argon, and 100% nitrogen).

With respect to crystallinity and phase, when a magnesium-zirconium oxide layer was formed on a layer of indium-tin oxide (ITO) in 100% argon (i.e., no nitridation), the high-k dielectric layer exhibited a significantly cubic and oriented columnar structure due to, at least in part, epitaxy between the ITO and the magnesium-zirconium oxide. When the gaseous environment was changed to 50% nitrogen and 50% argon, resulting in the formation/deposition of magnesium-zirconium oxynitride, the cubic/columnar structure and the epitaxy between the ITO and the high-k dielectric were reduced but still evident. The surface roughness of the high-k dielectric material/layer was also reduced. However, when the nitrogen concentration was increased to 100%, the magnesium-zirconium oxynitride exhibited little or no cubic/columnar structure and negligible surface roughness, at least when compared to the magnesium-zirconium oxide layer formed using 0% nitrogen. In some of the experiments, a layer of aluminum oxide was formed (e.g., also via PVD) above the magnesium-zirconium oxide (or magnesium-zirconium oxynitride). The reduction is surface roughness was evident at both the interface between the ITO and the high-k dielectric and the interface between the high-k dielectric and the aluminum oxide.

With respect to crystallinity, as the concentration of nitrogen in the processing chamber was increased, the high-k dielectric exhibited decreased grain size, and the sharpness of the interface boundary between the ITO and the high-k dielectric was reduced. When 100% nitrogen was used in the processing chamber, the resulting magnesium-zirconium oxynitride exhibited a micro-crystalline (or nano-crystalline) structure, instead of the rather coarse crystalline structure with large grains formed when 0% and 50% nitrogen was used.

With respect to the composition of the high-k dielectric material, some experimental data suggests that when using PVD to form/deposit the material, the gaseous environment in the chamber should be at least 50% nitrogen in order for the magnesium-zirconium oxynitride to include a significant amount of nitrogen. For example, with a gaseous environment of 50% nitrogen and 50% argon in the processing chamber, energy-dispersive X-ray spectroscopy (EDX) testing demonstrated that the concentration (i.e., atomic percentage) of nitrogen in the magnesium-zirconium oxynitride was close to background levels (e.g., about 2%). With 100% nitrogen, the concentration of nitrogen in the magnesium-zirconium oxynitride was between about 4% and about 5% (i.e., according to EDX testing). X-ray photoelectron spectroscopy (XPS) found the concentration of nitrogen in the material was 0% when the gaseous environment in the chamber was 25% nitrogen and about 2% (i.e., close to background levels) when the gaseous environment in the chamber was 50%.

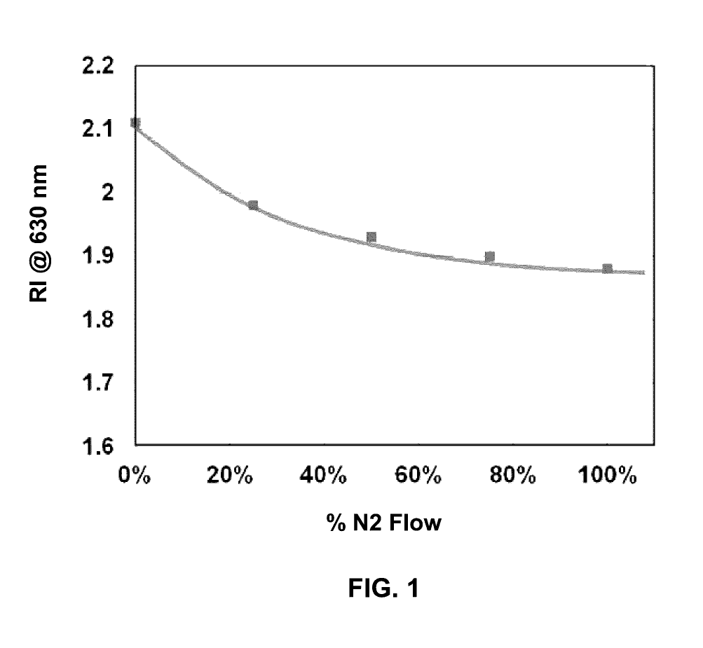

With respect to refractive index, some experimental data suggests that as the concentration of the nitrogen in the processing chamber (and/or the high-k dielectric material itself) increases, the refractive index decreases. For example, as shown in FIG. 1, when 0% nitrogen gas was used in the processing chamber, the refractive index of the material (i.e., magnesium-zirconium oxide) at a wavelength of 630 nanometers (nm) was about 2.10. As the concentration of nitrogen in the processing chamber was increased to 100%, the refractive index was monotonously reduced to about 1.88, perhaps due to phase and crystallinity change in the material (i.e., as the nitridation was increased). It should also be noted that the extinction coefficient (κ) of the material was 0 between 400 nm and 800 nm.

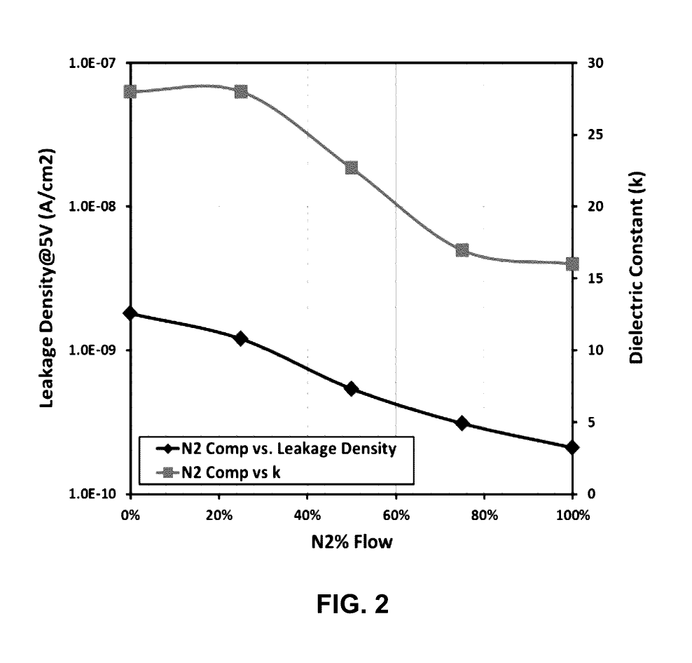

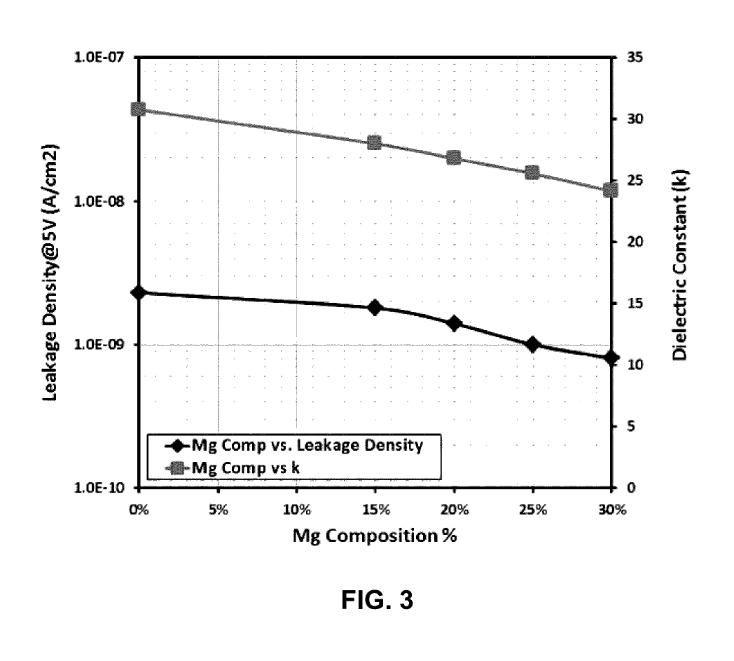

With respect to leakage density and dielectric constant, some experimental data suggests that as the concentration of the nitrogen in the processing chamber (and/or in the high-k dielectric material itself) increases, leakage density and dielectric constant decrease. For example, as shown in FIG. 2, as the concentration (or flow) of nitrogen gas in the PVD chamber was increased, the leakage density decreased in a relatively linear manner. As is also shown in FIG. 2, the dielectric constant of the high-k dielectric material was about 28 when the gaseous environment in the chamber was between about 0% and about 25% nitrogen, decreased relatively linearly (perhaps due to the change in crystallinity) as the concentration of nitrogen in the chamber was increased from about 25% and to about 75%, and remained relatively constant at about 16 as the gaseous environment in the chamber was increased from about 75% and to about 100%. However, referring now to FIG. 3, the leakage density and the dielectric constant were also reduced with an increase of magnesium in the magnesium-zirconium oxynitride, but the correlation was not as strong as it was with the increased nitrogen gas in the processing chamber.

With respect to dielectric relaxation, some experimental data suggests that as the concentration of the nitrogen in the processing chamber (and/or the high-k dielectric material itself) increases, the dielectric relaxation is lowered, with the lowest relaxation current resulting with 100% nitrogen, and that the impact of the increase of nitrogen gas in the processing chamber is relatively strong. The dielectric relaxation was also found to decrease with an increase of magnesium in magnesium-zirconium oxide (i.e., no nitridation) but this impact was relatively weak (i.e., weaker than the increase in nitrogen gas in the processing chamber when forming magnesium-zirconium oxynitride).

With respect to capacitance change with frequency, some experimental data suggests that as the concentration of the nitrogen in the processing chamber (and/or the high-k dielectric material itself) is changed, the capacitance change with frequency is modulated, and that the impact of the change of concentration of nitrogen gas in the processing chamber is relatively strong. The capacitance change with frequency was also found to modulate with changes in the concentration of magnesium in magnesium-zirconium oxide (i.e., no nitridation) but this impact was relatively weak.

As such, by controlling the amount of nitridation (i.e., the concentration of nitrogen) in the high-k dielectric materials, various properties of the material may be tuned, such as those described above. In some embodiments, data, such as described above, is gathered and stored (e.g., in a computing device and/or on a computer readable medium). The data may be used to create a collection (or library) of chemical compositions (e.g., recipes) for the high-k dielectric materials, along with the associated properties (and/or the values thereof). When a particular property (or value for a property) is desired in a high-k dielectric material, the data may then be used to select (or determine) and appropriate chemical composition (e.g., amount of nitridation) for the high-k dielectric material.

The desired high-k dielectric material may then be formed using the methods described above. The tuned high-k dielectric material(s) may be utilized in, for example, display storage capacitors, dynamic random-access memory (DRAM) devices, and other types of devices (e.g., semiconductor devices).

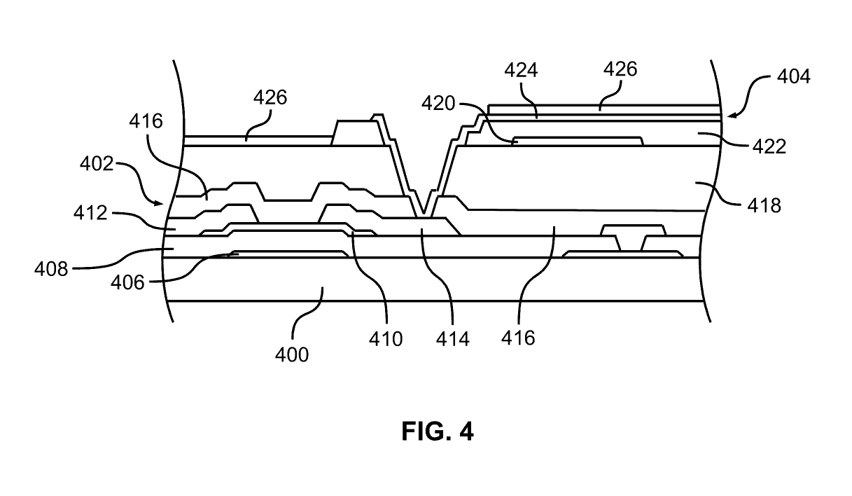

FIG. 4 illustrates an example of a device in which the tuned, nitrided high-k dielectric materials described above may be utilized according to some embodiments. Specifically, FIG. 4 illustrates a substrate 400 with a thin-film transistor (TFT) 402 and a storage capacitor 404 formed thereon. In some embodiments, the substrate 400 is transparent and is made of, for example, glass. The substrate 400 may have a thickness of, for example, between 0.01 and 0.5 centimeters (cm). Although only a portion of the substrate 400 is shown, it should be understood that the substrate 400 may have a width of, for example, between 5.0 cm and 4.0 meters (m). Although not shown, in some embodiments, the substrate 400 may have a dielectric layer (e.g., silicon oxide) formed above an upper surface thereof. In such embodiments, the components described below are formed above the dielectric layer.

With respect to the TFT 402 (e.g., inverted, staggered bottom-gate TFT), a gate electrode 406 is formed above the transparent substrate 400. In some embodiments, the gate electrode 406 is made of a conductive material, such as copper, silver, aluminum, manganese, molybdenum, or a combination thereof. The gate electrode 406 may have a thickness of, for example, between about 200 Å and about 5000 Å. Although not shown, it should be understood that in some embodiments, a seed layer (e.g., a copper alloy) is formed between the substrate 400 and the gate electrode 406.

It should be understood that the various components of the TFT 402 and the storage capacitor 404, such as the gate electrode 406 and those described below, are formed using processing techniques suitable for the particular materials being deposited, such as those described above (e.g., PVD, CVD, electroplating, etc.). Furthermore, it should be understood that the various components on the substrate 400, such as the gate electrode 406, may be sized and shaped using a photolithography process and an etching process, as is commonly understood, such that the components are formed above selected regions of the substrate 400.

Still Referring to FIG. 4, a gate dielectric layer 408 is formed above the gate electrode 406 and the exposed portions of the substrate 400. The gate dielectric layer 408 may be made of, for example, silicon oxide, silicon nitride, or a high-k dielectric (e.g., having a dielectric constant greater than 3.9), such as zirconium oxide, hafnium oxide, or aluminum oxide, or the nitridized high-k dielectric materials described above. In some embodiments, the gate dielectric layer 408 has a thickness of, for example, between about 100 Å and about 5000 Å.

A channel layer (or active layer) 410 is formed above the gate dielectric layer 408, over the gate electrode 406. The channel layer 410 may include (e.g., be made of), for example, amorphous silicon, polycrystalline silicon, or indium-gallium-zinc oxide (IGZO). The channel layer 410 may have a thickness of, for example, between about 100 Å and about 1000 Å.

A source region (or electrode) 412 and a drain region (or electrode) 414 are formed above the channel layer 410. As shown, the source region 412 and the drain region 414 lie on opposing sides of, and partially overlap the ends of, the channel layer 410. In some embodiments, the source region 412 and the drain region 414 are made of titanium, molybdenum, copper, copper-manganese alloy, or a combination thereof. The source region 412 and the drain region 414 may have a thickness of, for example, between about 200 Å and 5000 Å.

A passivation layer 416 is formed above the channel layer 410, the source region 412, the drain region 414, and the gate dielectric layer 408. In some embodiments, the passivation layer 416 is made of silicon oxide, silicon nitride, aluminum oxide, aluminum nitride, or a combination thereof and has a thickness of, for example, between about 1000 Å and about 1500 Å.

A resin layer 418 is formed above the passivation layer 416. In some embodiments, the resin layer 418 includes (e.g., is made of) an acrylic resin and may have a thickness of, for example, between about 1000 Å and about 1500 Å.

The storage capacitor 404 is formed above the resin layer 418 and includes a bottom electrode 420, a dielectric layer (or dielectric layer stack) 422, and a top electrode 424, each of which may have a thickness of, for example between about 500 Å and about 1500 Å. The bottom electrode 420 and the top electrode 424 may be made of, for example, ITO, a metal, or a metal nitride. The dielectric layer 422 may include, for example, the nitrided high-k dielectric materials described above. In the embodiment depicted in FIG. 4, the top electrode extends into a via (or trench) formed through the resin layer 418 and the passivation layer 416 and in electrically connected to the drain region 414.

Still referring to FIG. 4, an alignment film 426 is formed above the storage capacitor 404 and the portion of the resin layer 418 above the TFT 402. The alignment 426 film may, for example, include (e.g., be made of) polyimide and/or carbon and have a thickness of between about 3 Å and about 1000 Å.

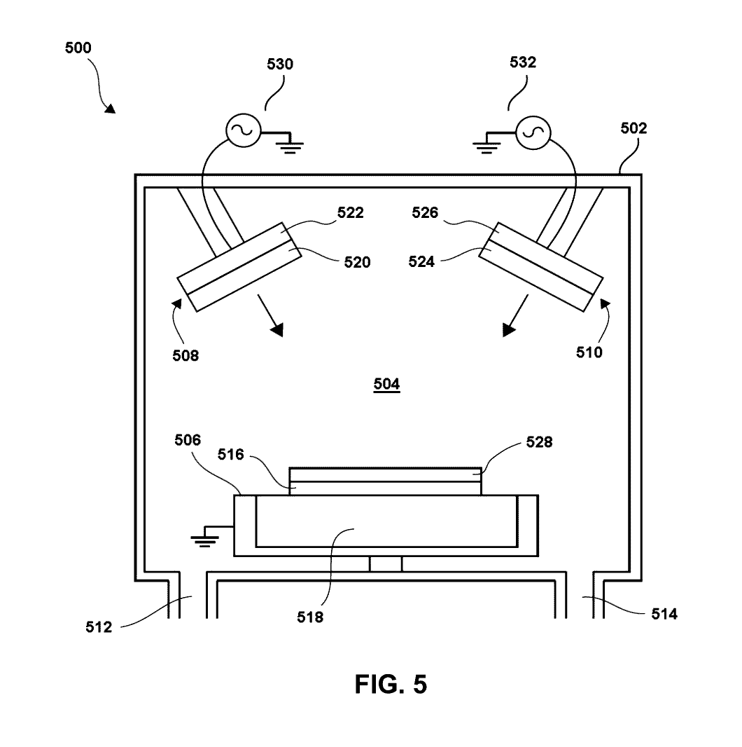

FIG. 5 provides a simplified illustration of a physical vapor deposition (PVD) tool (and/or system) 500 which may be used, in some embodiments, to form the high-k dielectric materials described above. The PVD tool 500 shown in FIG. 5 includes a housing 502 that defines, or encloses, a processing chamber 504, a substrate support 506, a first target assembly 508, and a second target assembly 510.

The housing 502 includes a gas inlet 512 and a gas outlet 514 near a lower region thereof on opposing sides of the substrate support 506. The substrate support 506 is positioned near the lower region of the housing 502 and in configured to support a substrate 516. The substrate 516 may be a round glass (e.g., borosilicate glass) substrate (or include a semiconductor material, such as silicon) and have a diameter of, for example, about 200 mm or about 300 mm. In other embodiments (such as in a manufacturing environment), the substrate 516 may have other shapes, such as square or rectangular, and may be significantly larger (e.g., about 0.5-about 6 m across). The substrate support 506 includes a support electrode 518 and is held at ground potential during processing, as indicated.

The first and second target assemblies (or process heads) 508 and 510 are suspended from an upper region of the housing 502 within the processing chamber 504. The first target assembly 508 includes a first target 520 and a first target electrode 522, and the second target assembly 510 includes a second target 524 and a second target electrode 526. As shown, the first target 520 and the second target 524 are oriented or directed towards the substrate 516. As is commonly understood, the first target 520 and the second target 524 include one or more materials that are to be used to deposit a layer of material 528 on the upper surface of the substrate 516. The materials used in the targets 520 and 524 may include, for example, magnesium, zirconium, hafnium, titanium, and/or combinations thereof. Additionally, the materials used in the targets may include oxygen, nitrogen, or a combination of oxygen and nitrogen in order to form oxides, nitrides, and oxynitrides. Additionally, although only two targets 520 and 524 are shown, additional targets may be used.

The PVD tool 500 also includes a first power supply 530 coupled to the first target electrode 522 and a second power supply 532 coupled to the second target electrode 524. As is commonly understood, the power supplies 530 and 532 pulse direct current (DC) power to the respective electrodes, causing material to be, at least in some embodiments, simultaneously sputtered (i.e., co-sputtered) from the first and second targets 520 and 524.

During sputtering, inert gases, such as argon or krypton, may be introduced into the processing chamber 504 through the gas inlet 512, while a vacuum is applied to the gas outlet 514. However, in embodiments in which reactive sputtering is used, reactive gases may also be introduced, such as oxygen and/or nitrogen, which interact with particles ejected from the targets (i.e., to form oxides, nitrides, and/or oxynitrides).

Although not shown in FIG. 5, the PVD tool 500 may also include a control system having, for example, a processor and a memory, which is in operable communication with the other components shown in FIG. 5 and configured to control the operation thereof in order to perform the methods described herein.

Further, although the PVD tool 500 shown in FIG. 5 includes a stationary substrate support 506, it should be understood that in a manufacturing environment, the substrate 516 may be in motion (e.g., an in-line configuration) during the formation of various materials described herein.

Thus, in some embodiments, high-k dielectric materials, and methods for forming such materials, are provided. A property of the high-k dielectric material is selected. A value of the selected property of the high-k dielectric material is selected. A chemical composition of the high-k dielectric material is selected from a plurality of chemical compositions of the high-k dielectric material. The selected chemical composition of the high-k dielectric material includes an amount of nitridation associated with the selected value of the selected property of the high-k dielectric material. The high-k dielectric material is formed with the selected chemical composition of the high-k dielectric material.

The selected property of the high-k dielectric material may be crystallinity, phase, refractive index, leakage density, dielectric constant, dielectric relaxation, capacitance change with frequency, or a combination thereof. The nitridized high-k dielectric material may include magnesium-zirconium oxynitride, zirconium oxynitride, hafnium oxynitride, titanium oxynitride, or a combination thereof. The nitridation of the high-k dielectric material may be performed during the formation of the high-k dielectric material (i.e., in-situ) or after the formation of a non-nitridized high-k dielectric material (i.e., ex-situ). The nitridation of the high-k dielectric material performed during the formation of the high-k dielectric material may be performed during a PVD process by introducing nitrogen gas into the PVD processing chamber.

Although the foregoing examples have been described in some detail for purposes of clarity of understanding, the invention is not limited to the details provided.

There are many alternative ways of implementing the invention. The disclosed examples are illustrative and not restrictive.

What is claimed:

1. A method for forming a high-k dielectric material, the method comprising:
selecting a property of a high-k dielectric material;
selecting a value of the selected property of the high-k dielectric material;
selecting a chemical composition of the high-k dielectric material from a plurality of chemical compositions of the high-k dielectric material, wherein the selected chemical composition of the high-k dielectric material comprises an amount of nitridation associated with the selected value of the selected property of the high-k dielectric material; and
forming the high-k dielectric material with the selected chemical composition of the high-k dielectric material.

2. The method of claim 1, wherein the selected property of the high-k dielectric material comprises at least one of phase, crystallinity, refractive index, dielectric constant, dielectric relaxation, capacitance vs. frequency dependence, leakage density, or a combination thereof.

3. The method of claim 1, wherein the high-k dielectric material comprises at least one of magnesium-zirconium oxynitride, zirconium oxynitride, hafnium oxynitride, titanium oxynitride, or a combination thereof.

4. The method of claim 2, wherein the high-k dielectric material is formed using a deposition process in a gaseous environment comprising nitrogen gas.

5. The method of claim 4, wherein the selected property of the high-k dielectric material comprises phase, crystallinity, or a combination thereof, and the gaseous environment comprises at least 50% nitrogen gas.

6. The method of claim 4, wherein the selected property of the high-k dielectric material comprises refractive index, and the gaseous environment consists of nitrogen gas.

7. The method of claim 4, wherein the selected property of the high-k dielectric material comprises leakage density, dielectric constant, or a combination thereof, and the gaseous environment comprises at least 25% nitrogen gas.

8. The method of claim 2, wherein the forming of the high-k dielectric material comprises:
forming a non-nitridized high-k dielectric material; and
performing a nitridization process on the non-nitridized high-k dielectric material after the forming of the non-nitridized high-k dielectric material.

9. The method of claim 8, wherein the nitridization process comprises a remote plasma treatment, a direct plasma treatment, or a combination thereof.

10. The method of claim 8, wherein the nitridization process comprises a gas treatment, an annealing process, a chemical treatment, or a combination thereof.

11. A method for forming a high-k dielectric material, the method comprising:
selecting a property of a high-k dielectric material, wherein the selected property of the high-k dielectric material comprises at least one of phase, crystallinity, refractive index, dielectric constant, dielectric relaxation, capacitance vs. frequency dependence, leakage density, or a combination thereof;
selecting a value of the property of the high-k dielectric material;
selecting a chemical composition of the high-k dielectric material from a plurality of chemical compositions of the high-k dielectric material, wherein the selected chemical composition of the high-k dielectric material comprises an amount of nitridation associated with the selected value of the selected property of the high-k dielectric material; and
forming the high-k dielectric material with the selected chemical composition of the high-k dielectric material using physical vapor deposition (PVD) in a gaseous environment comprising nitrogen gas.

12. The method of claim 11, wherein the high-k dielectric material comprises at least one of magnesium-zirconium oxynitride, zirconium oxynitride, hafnium oxynitride, titanium oxynitride, or a combination thereof.

13. The method of claim 11, wherein the selected property of the high-k dielectric material comprises phase, crystallinity, or a combination thereof, and the gaseous environment comprises at least 50% nitrogen gas.

14. The method of claim 11, wherein the selected property of the high-k dielectric material comprises refractive index, and the gaseous environment consists of nitrogen gas.

15. The method of claim 11, wherein the selected property of the high-k dielectric material comprises leakage density, dielectric constant, or a combination thereof, and the gaseous environment comprises at least 25% nitrogen gas.

16. A method for forming a high-k dielectric material, the method comprising:
selecting a property of a high-k dielectric material;
selecting a value of the property of the high-k dielectric material;
selecting a chemical composition of the high-k dielectric material from a plurality of chemical compositions of the high-k dielectric material, wherein the selected chemical composition of the high-k dielectric material comprises an amount of nitridation associated with the selected value of the selected property of the high-k dielectric material; and
forming the high-k dielectric material with the selected chemical composition of the high-k dielectric material, wherein the forming the high-k dielectric material comprises forming a non-nitridized high-k dielectric material and performing a nitridization process on the non-nitridized high-k dielectric material after the forming of the non-nitridized high-k dielectric material.

17. The method of claim 16, wherein the high-k dielectric material comprises at least one of magnesium-zirconium oxynitride, zirconium oxynitride, hafnium oxynitride, titanium oxynitride, or a combination thereof.

18. The method of claim 17, wherein the selected property of the high-k dielectric material comprises at least one of phase, crystallinity, refractive index, dielectric constant, dielectric relaxation, capacitance vs. frequency dependence, leakage density, or a combination thereof.

19. The method of claim 18, wherein the nitridization process comprises a remote plasma treatment, a direct plasma treatment, or a combination thereof.

20. The method of claim 18, wherein the nitridization process comprises a gas treatment, an annealing process, a chemical treatment, or a combination thereof.
